(19) United States
(12) Patent Application Publication
(10) Pub. No.: US 2025/0221299 A1
(43) Pub. Date: Jul. 3, 2025

(54) Optoelectronic Device Comprising Single Crystals of Hybrid Organic-Inorganic Perovskite, and Method for Producing Said Single Perovskite Crystals

(71) Applicants: Istituto Nazionale Di Fisica Nucleare, Roma (IT); Consiglio Nazionale Delle Ricerche, Roma (IT)

(72) Inventors: Marianna Testa, Frascati (IT); Ilenia Viola, Roma (IT); Luisa De Marco, Lecce (IT); Matthias Auf Der Maur, Roma (IT); Fabio Matteocci, Roma (IT)

(21) Appl. No.: 18/867,131

(22) PCT Filed: May 11, 2023
(86) PCT No.: PCT/IB2023/054876

§ 371 Date: Nov. 19, 2024

(30) Foreign Application Priority Data
May 20, 2022 (IT) 102022000010502

(51) Int. Cl. H10K 85/50; C30B 7/00; C30B 29/12; C30B 29/62; H10K 71/60

(52) U.S. Cl. CPC H10K 85/50; C30B 7/00; C30B 29/12; C30B 29/62; H10K 71/60

(57) ABSTRACT

Described herein is an optoelectronic device comprising: a substrate; an active layer made from at least one perovskite microwire having a longitudinal extension and having a first surface in contact with said substrate; a first electrode deposited on said substrate; a second electrode made of electrically conductive material and comprising a central tract, deposited in contact with a second surface of said at least one microwire, said second surface being opposite to said first surface.

### FIELD OF THE INVENTION

The present invention concerns, in general, the optoelectronics field. In particular, the present invention relates to an optoelectronic device comprising single crystals of hybrid organic-inorganic perovskite in the form of microwires, and a method for obtaining such crystals.

### DESCRIPTION OF THE PRIOR ART

As is known, organometal halide perovskites (OMHP) are promising materials for use as semiconductors, which provide high performance for the detection of photons in the visible range and ionizing radiations.

OMHP-based optoelectronic devices are known which are produced by implementing polycrystalline thin film and single-crystal (SC) technologies, using, for example, low-cost and low-temperature processes of growth from solution.

Due to their intrinsic polycrystalline nature, OMHP films suffer from lower material quality (which is influenced, for example, by grain boundaries and defects) in comparison with SCs.

Furthermore, standard deposition techniques, such as spin coating or blade coating, are generally limited to films having a thickness of about 500-600 nm.

On the other hand, single crystals (SCs), while they have been widely studied due to their excellent properties, are often unsuitable for integration into a complete optoelectronic device because of their unfavourable aspect ratio (the ratio between lateral dimensions and thickness).

However, OMHPs structured with periodic micropatterns or nanopatterns have recently attracted much interest on account of the improved efficiency of a single device, due to a controlled arrangement of single crystals within a confined geometry, and also of the possibility of using technologies for deposition of a device as pixel arrays, suitable for future mass production.

As concerns the fabrication of perovskite SCs for high-efficiency devices, X. Y. Yang, et al., in “Patterned Perovskites for Optoelectronic Applications”, Small Methods 2, 1800110 (2018), describes a variety of bottom-up production techniques for producing single crystals, including growth induced by solvent evaporation (see the article by H. Deng, et al., “Growth, patterning and alignment of organolead iodide perovskite nanowires for optoelectronic devices”, Nanoscale 7, 4163 (2015)), growth in confined environment (see the article by J. Mao, et al. “Novel Direct Nanopatterning Approach to Fabricate Periodically Nanostructured Perovskite for Optoelectronic Applications”, Adv. Funct. Mater. 27, 1606525 (2017)), and template-guided growth (see the article by L. Lee, et al., “Wafer-scale single-crystal perovskite patterned thin films based on geometrically-confined lateral crystal growth”, Nat. Comm. 8, 15882 (2017)).

In this respect, non-conventional soft lithography techniques, already widely employed for deposition of delicate photoactive materials, have proved to be strategical, as described by B. Jeong et al. in “Micro- and Nanopatterning of Halide Perovskites Where Crystal Engineering for Emerging Photoelectronics Meets Integrated Device Array Technology”, Adv. Mater., 32, 2000597 (2020).

The Applicant observes that experimental results suggest that the intrinsic crystallization properties of perovskites could be modified by controlling the intermediate state during crystallization. In this regard, see for example the following articles:
C. Wehrenfennig, et al., “High Charge Carrier Mobilities and Lifetimes in Organolead Trihalide Perovskites”, Adv. Mater., 26, 1584 (2014); and
P.-W. Liang, et al., “Additive Enhanced Crystallization of Solution Processed Perovskite for Highly Efficient Planar Heterojunction Solar Cells”, Adv. Mater., 26, 3748 (2014).

For this purpose, non-destructive bottom-up technologies (including microfluidics, confined self-assembly, ink-jet printing) have shown to provide effective control over the self-assembly kinetics to give extremely functional structures, as described by S. X. Li et al. in:
“Template-confined growth of Ruddlesden-Popper perovskite micro-wire arrays for stable polarized photodetectors”, Nanoscale, 11, 18272 (2019); and
“Perovskite Single-Crystal Microwire-Array Photodetectors with Performance Stability beyond 1 Year”, Adv. Mater. 2001998 (2020).

### BRIEF DESCRIPTION OF THE INVENTION

It is the object of the present invention to provide a method for making a single perovskite crystal suitable for use in a vertical optoelectronic device.

In particular, the present invention aims at providing a method for producing a single perovskite crystal that permits obtaining:
high quality of the active material in terms of crystallinity and morphological characteristics;
high aspect ratio;
single-step growth process directly on the patterned substrate integratable in the complete device;
crystal thickness defined a priori;
predetermined device geometry.

According to the present invention, said method comprises:
providing a substrate;
applying a microstructured polymeric template onto said substrate, said microstructured template comprising, on the surface thereof facing said substrate, a plurality of microchannels that are parallel to one another;
wherein said microchannels have:
a width (W) in the range of 15 to 300 μm;
a thickness (H) in the range of 500 nm to 50 μm;
a distance (D) between adjacent microchannels greater than 50 μm;
filling said microchannels with an ABX3 perovskite precursor solution,
where A is a cation; B is a metallic cation, and X is a halide;
the molarity of said perovskite precursor solution is in the range of 0.3 M to 1.4 M in an organic solvent;
modulating the solvent evaporation kinetics by varying:
   the growth temperature of said perovskite crystals between 2° C. and 30° C.;
   the energetic properties at the channel interface by using different types of wettability and functionalization and maintaining average hydrophobicity conditions;
   the speed of movement of the precursor liquid within the microchannels, as the resultant of the combination between the temperature and wettability parameters.

Preferably, A is a cation selected from: caesium, formamidinium or methylammonium.

Preferably, B is a metallic cation selected from: Pb2⁺ or Sn2⁺.

Preferably, X is a halide selected from: Cl⁻, Br⁻, or I⁻.

According to a further aspect, the present invention provides a process for making an optoelectronic device comprising:
providing a substrate, preferably made of ITO;
making a plurality of non-conductive lines on a surface of said substrate, thereby forming a first portion, a second portion and a third portion of the surface;
making, in said first portion, a plurality of microwires as described above;
depositing a first electrode;
depositing a second electrode.

Preferably, said plurality of non-conductive lines are made by laser ablation.

The Applicant observes that, when making the optoelectronic device as described above, an ideal geometry of the device can be established, wherein the patterning of the substrate, the geometry of the crystal and the upper contacts are designed, so that the device can be fabricated semi-automatically using predefined templates.

Advantageously, this method makes it possible to modulate the solvent evaporation kinetics, and hence the oversaturation levels of the perovskite solution within a microchannel.

Advantageously, it is possible to control the size and shape of the obtained microcrystals.

By varying the internal pressure, the temperature, the wettability and the functionalization at the microchannels' interface, it is possible to adjust the crystal growth rate and hence the quality of the SCs.

Advantageously, this method ensures reproducibility and fast fabrication of the optoelectronic device, because the process does not need to be re-adapted from time to time, as is the case with randomly transferred or grown crystals.

According to a further aspect, the present invention provides an optoelectronic device comprising:
a substrate, preferably made of ITO;
an active layer made from at least one microwire of perovskite having a longitudinal extension and having a first surface in contact with said substrate;
a first electrode deposited on said substrate;
a second electrode made of electrically conductive material and comprising a central tract, deposited in contact with a second surface of said at least one microwire, said second surface being opposite to said first surface.

Preferably, the at least one microwire is made as a single crystal of hybrid organic-inorganic perovskite.

Preferably, said device comprises a plurality of microwires that are parallel to one another.

Preferably, the at least one microwire has a width in the range of 15 to 300 μm, a length in the range of 100 to 2,000 μm, and a thickness in the range of 0.5 to 50 μm.

Preferably, the at least one microwire has an aspect ratio in the range of 1,000 to 1,800.

Preferably, said first electrode is made by depositing a metal onto a portion of said substrate delimited by non-conductive lines.

Preferably, said central tract of said second electrode is orthogonal to the major dimension of said at least one microwire, and preferably has a size of 500 μm×140 μm.

Preferably, at the respective extremities of said central tract of said second electrode, said first electrode has two pads, preferably rectangular in shape, deposited on respective portions of said substrate. Said portions being preferably delimited by non-conductive lines.

Preferably, said non-conductive lines are formed on said substrate, delimiting said portions of said substrate whereon said first electrode and said second electrode are deposited, said non-conductive lines having preferably a size of 70 μm×3.93 mm.

Advantageously, said optoelectronic device has perovskite crystals on patterned non-conductive substrates, permitting the fabrication of a photosensor or other types of vertical optoelectronic devices, i.e. a device having a positive contact and a negative contact on opposite faces of the same perovskite crystal.

### BRIEF DESCRIPTION OF THE DRAWINGS

The invention will become more apparent in light of the following detailed description, provided merely by way of non-limiting example, wherein reference will be made to the annexed drawings, wherein:

FIG. 1 is a schematic perspective view of an optoelectronic device according to the present invention;

FIG. 2 is a plan view of the device of FIG. 1;

FIG. 3 shows a diagram of the template used for making a perovskite crystal;

FIG. 4 is a flow chart of a method for making perovskite crystals according to the present invention.

The drawings are not in scale.

### DETAILED DESCRIPTION OF SOME PREFERRED EMBODIMENTS

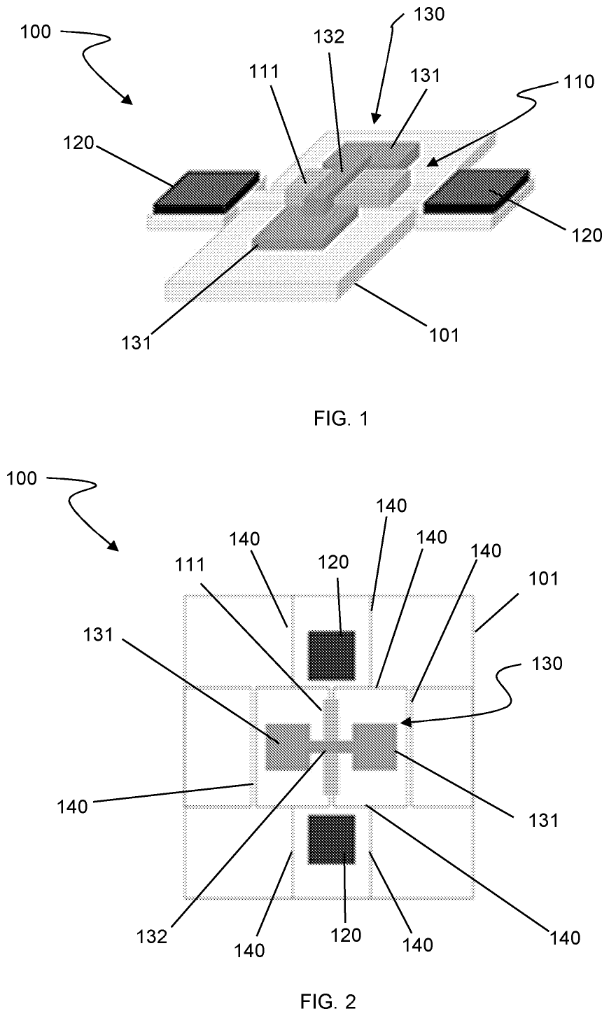

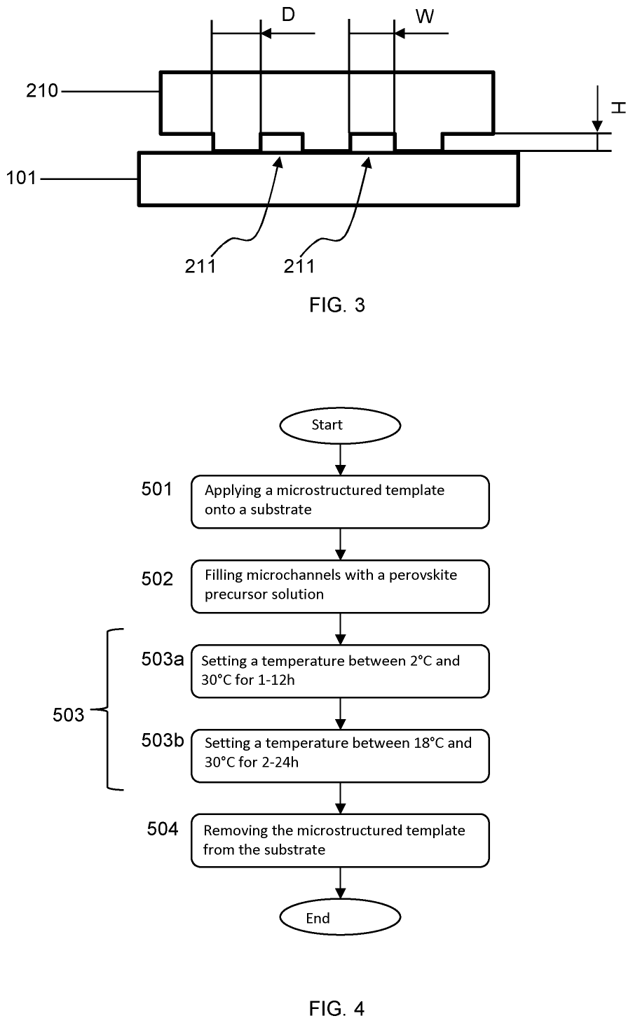

With initial reference to FIGS. 1 and 2, the present invention provides an optoelectronic device 100.

The device 100 comprises a substrate 101. The substrate 101 is a substrate preferably made of a material selected from: ITO (Indium Tin Oxide) or silicon.

As shown in FIG. 2, non-conductive lines 140 are formed on the surface of said substrate 101. The non-conductive lines delimit portions of said substrate 101. The non-conductive lines 140 having preferably a size of 70 μm×3.93 mm.

On such portions a first electrode 120 and a second electrode 130, made of an electrically conductive material, are deposited. For example, the first electrode 120 and the second electrode 130 are made of metal, in particular gold or silver.

The device 100 comprises an active layer 110. The active layer 110 is positioned on a surface of said substrate 101.

The active layer 110 comprises at least one microwire 111 of perovskite having a longitudinal extension and having a first surface in contact with the surface of the substrate 101;

The second electrode 130 comprises a central tract 132. The central tract 132 is deposited in contact with a second surface of the at least one microwire 111, the second surface being opposite to that surface of the microwire which is in contact with the substrate 101. In particular, the central tract 132 of the second electrode 130 is orthogonal to the major dimension of at least one microwire 111. Preferably, the central tract 132 has, at the microwire 111, a size in the range of 10 to 200 μm, e.g. 140 μm.

Preferably, the at least one microwire is made as a single crystal of hybrid organic-inorganic perovskite.

Preferably, the device 100 comprises a plurality of microwires 111 that are parallel to one another. Each microwire 111 has a width in the range of 15 to 300 μm, a length in the range of 100 to 2,000 μm, and a thickness in the range of 0.5 to 50 μm.

Preferably, each microwire 111 has an aspect ratio (i.e. the ratio between the length and the width of the microwire) in the range of 1,000 to 1,800, more preferably 1,600.

As shown in FIG. 2, at the respective extremities of the central tract 132 of the second electrode 130 two pads 131 are formed, preferably rectangular in shape, which are deposited on respective portions of said substrate 101. Such pads 131 substantially correspond to the negative terminal of the device 100.

Preferably, also the first electrode 120 is made as two rectangular pads 120. As shown in FIGS. 1 and 2, such two pads 120 are positioned in such a way that an axis connecting the two pads 120 from centre to centre is parallel to the axis of longitudinal development of at least one microwire 111 and/or perpendicular to the first tract 132 of the second electrode 130.

Preferably, as aforementioned, non-conductive lines 140 are formed on the surface of the substrate 101, delimiting portions of the substrate 101. On such portions metallic materials are deposited. Such portions of the substrate 101 delimited by non-conductive lines, whereon metallic materials are deposited, define the first electrode 120 and the second electrode 130.

Preferably, the non-conductive lines 140 delimit the active layer 110.

Preferably, in the portion of the substrate 101 where the first electrode 120 and/or the second electrode 130 are made, a silver paste is deposited. The silver paste facilitates the electric contact with an external reading system.

According to a further aspect, with reference to FIG. 4, the present invention provides a method for making at least one perovskite microwire 111 on a substrate 101.

Such method comprises starting a first phase 501 of preparing a substrate 101, e.g. a substrate 101 made of ITO. During phase 501, a microstructured template 210 is applied onto the substrate 101. The microstructured template 210 comprising, on the surface thereof facing the substrate 101, a plurality of microchannels 211 that are parallel to one another. The microchannels 211 have a width W in the range of 15 to 300 μm; a thickness H in the range of 500 nm to 50 μm; and a distance D between adjacent microchannels that is greater than or equal to 50 μm. The microstructured template 210 being made of a polymeric material, e.g. polydimethylsiloxane (PDMS), wherein the microchannels 210 are made by soft lithography.

Starting a phase 502 wherein the microchannels 210 are filled with an ABX3 perovskite precursor solution, where A is a cation; B is a metallic cation, and X is a halide. For example, A is a cation selected from: caesium, formamidinium or methylammonium; B is a metallic cation selected from: Pb2⁺ or Sn2⁺; and X is a halide selected from: Cl⁻, Br⁻, or I⁻. Such precursor solution having preferably a molarity in the range of 0.3 M to 1.4 M in an organic solvent. Preferably, the molarity used for obtaining crystals of the described size will be in the range of 0.8 M to 1.2 M.

Once the microchannels 210 have been filled, a perovskite crystal nucleation phase 503 is started. During phase 503, the growth of the perovskite crystals is obtained by means of two nucleation sub-phases, wherein:
in a first sub-phase 503a, the temperature used during the growth of the perovskite crystals is maintained in the range of 2° C. to 30° C., preferably 2° C. to 4° C.;
the first sub-phase 503a lasts for a time interval of 1 to 12 h,
in a second sub-phase 503b, following said first sub-phase 503a, the temperature is maintained within a range of 18° C. to 30° C.;
the second sub-phase 503b lasts for a time interval of 2 to 24 h.

At the end of said second sub-phase, complete growth of perovskite crystals is obtained within the microchannels 211.

Preferably, the energetic properties at the interface of the microchannels 211 during phase 503 are modulated by substrate wettability and functionalization. For example, wettability is maintained under a condition of average hydrophobicity; for example, wettability is kept within contact angle values of 50° to 110°.

At the end of the sub-phase 503b, the microstructured template 210 is removed from the substrate 101 (phase 504).

At the end of the above-described method, a substrate 101 is obtained which has an active zone 110 comprising a plurality of microwires 111.

According to a further aspect, once the substrate 101 comprising the active zone 110 has been obtained, it is possible to fabricate the optoelectronic device 100.

In particular, the device 100 is fabricated by depositing the first electrode 120 in such a way as to obtain a first tract 132 and two pads 131, and by depositing a second electrode 120, as described above. For example, gold strips 132, orthogonal to the major dimension of the microwires 111, are deposited as the upper contact onto the microwires 111. The gold strips 132 end with pads 131 that allow supplying the reverse polarization voltage to the device 100. The reverse polarization voltage is applied across a gold pad 131 (i.e. the pad 131 of the second electrode 130) and a further pad 120 of conductive material (i.e. the first electrode 120) deposited on the surface of the substrate 101, preferably near the active layer 110, e.g. at a distance of 1 mm to 3 mm from a peripheral zone of the active layer 110 or from a non-conductive line 140 delimiting the active layer 110.

Preferably, non-conductive lines 140 are formed by laser ablation on the substrate 101, such non-conductive lines being made, for example, prior to growing the microwires 111 as described above.

The Applicant observes that it is possible to use a silicon substrate 101 with CMOS integrated electronics (e.g. the CMOS integrated electronics is positioned at the first and/or second electrodes 120, 130 and/or CMOS sensors are connected to the first and/or second electrodes 120, 130). Such a substrate permits the fabrication of, for example, an X-ray detector. For such an application, the active layer 110 is preferably made from microwires 111 having a thickness in the range of 50 to 100 μm. Such microwires 111 are preferably made by following the above-described method.

Alternatively, a gamma-ray detector can be fabricated. In particular, considering such an application, the microwires 111 10 comprised in the active layer 110 have, preferably, a thickness of approx. 1 mm, e.g. 1 mm±20%, preferably ±10%, even more preferably ±5%. Such microwires 111 are preferably made by following the above-described method.

1. An optoelectronic device comprising:
a substrate;
an active layer on a surface of said substrate, made from at least one microwire of perovskite having a longitudinal extension and having a first surface in contact with said substrate;
a first electrode formed on said surface of said substrate, said first electrode being made of electrically conductive material;
a second electrode formed on said surface, said second electrode being made of electrically conductive material and comprising a central tract, deposited in contact with a second surface of said at least one microwire, said second surface being opposite to said first surface.

2. The device according to claim 1, wherein the at least one microwire is made from a single crystal of hybrid organic-inorganic perovskite.

3. The device according to claim 1, wherein said device comprises a plurality of microwires that are parallel to one another.

4. The device according to claim 1, wherein the at least one microwire has a width in the range of 15 to 300 μm, a length in the range of 100 to 2,000 μm, and a thickness in the range of 0.5 to 50 μm.

5. The device according to claim 1, wherein the at least one microwire has an aspect ratio in the range of 1,000 to 1,800.

6. The device according to claim 1, wherein said first electrode is made by deposition of a metal on a portion of said substrate.

7. The device according to claim 1, wherein said central tract of said second electrode is orthogonal to the major dimension of said at least one microwire.

8. The device according to claim 1, wherein, at the respective extremities of said central tract of said second electrode, said first electrode has two pads deposited on respective portions of said substrate (101).

9. The device according to claim 6, wherein non-conductive lines are formed on the surface of said substrate, delimiting said portions of said substrate whereon said first electrode and said second electrode are deposited.

10. A method for making at least one microwire of perovskite on a substrate, comprising:
providing a substrate;
applying a microstructured template onto said substrate, said microstructured template comprising, on the surface thereof facing said substrate, a plurality of microchannels parallel to one another;
wherein said microchannels have:
a width (W) in the range of 15 to 300 μm;
a thickness (H) in the range of 500 nm to 50 μm;
a distance (D) between adjacent microchannels greater than or equal to 50 μm;
filling said microchannels with a volume of an ABX3 perovskite precursor solution,
where A is a cation; B is a metallic cation, and X is a halide;
starting a phase of growth of said perovskite crystals, comprising:
a first nucleation phase, in which a temperature of growth of the perovskite crystals is maintained in the range of 2° C. to 30° C., preferably 2° C. to 4° C., for a time interval of 1 to 12 h.
a second nucleation phase, following said first nucleation phase, in which the temperature of growth of the perovskite crystals is maintained in the range of 18° C. to 30° C. for a time interval of 2 to 24 h.

11. The method according to claim 10, wherein during the growth phase wettability is maintained within contact angle values of 50° to 110°.

12. The method according to claim 10, wherein a molarity of said perovskite precursor solution is in the range of 0.8 M to 1.2 M in an organic solvent.

13. The method according to claim 10, wherein A is a cation selected from: caesium, formamidinium or methylammonium; B is a metallic cation selected from: Pb2+ or Sn2+); and X is a halide selected from: Cl—, Br—, or I—.

14. Process for making an optoelectronic device, comprising:
providing a substrate;
making a plurality of non-conductive lines on a surface of said substrate, thereby forming a first portion, a second portion and a third portion of the surface;
making, in said first portion, a plurality of microwires in accordance with the method of claim 10;
depositing a first electrode;
depositing a second electrode.

15. The device according to claim 7, wherein said central tract has a size of 500 μm×140 μm.

16. The device according to claim 8, wherein the two pads are rectangular in shape.

17. The device according to claim 9, wherein the non-conductive lines have a size of 70 μm×3.93 mm.
